(19) United States
(12) Patent Application Publication
(10) Pub. No.: US 2026/0255980 A1
(43) Pub. Date: Aug. 27, 2026

(54) ALIGNMENT MARK FOR SILICON CARBIDE SEMICONDUCTOR PROCESS AND MANUFACTURING METHOD THEREOF

(71) Applicant: ProAsia Semiconductor Corporation, Hsinchu City (TW)

(72) Inventors: Meng-Wei Wu, Hsinchu City (TW); Ting-Lu Tuan, Hsinchu City (TW); Yi-Hsiang Chien, Hsinchu City (TW); Tsai-Chun Chien, Hsinchu City (TW)

(21) Appl. No.: 19/307,818

(22) Filed: Aug. 22, 2025

(30) Foreign Application Priority Data
Feb. 24, 2025 (TW) 114106771

(51) Int. Cl. H01L 23/544; H10D 62/832

(52) U.S. Cl. CPC H10W 46/00; H10D 62/8325; H10W 46/301

(57) ABSTRACT

An alignment mark for silicon carbide semiconductor process and a manufacturing method thereof are provided. The alignment mark for silicon carbide semiconductor process is formed on a silicon carbide epitaxial layer of a silicon carbide substrate and includes at least one trench structure and an ion doped interface. The at least one trench structure is disposed in the silicon carbide epitaxial layer, and the ion doped interface is disposed at a bottom of the at least one trench structure.

### CROSS-REFERENCES TO RELATED APPLICATIONS

This application claims the benefit of priority to Taiwanese Patent Application No. 114106771 filed on Feb. 24, 2025, which is hereby incorporated by reference in its entirety.

### BACKGROUND OF THE INVENTION

### Field of the Invention

This invention relates to an alignment mark for silicon carbide semiconductor process and a manufacturing method thereof, and in particular to a high-contrast alignment mark for silicon carbide semiconductor process and a manufacturing method thereof.

### Descriptions of the Related Art

Due to the material properties and manufacturing challenges of silicon wafers and silicon carbide substrates, there are some key differences in the alignment methods used in their respective semiconductor processes. For example, in optical alignment, silicon wafers are transparent to certain wavelengths of visible light, and their smooth, polished surfaces allow for clear pattern recognition using optical microscopes. However, silicon carbide substrates are highly opaque to visible light, which makes traditional optical alignment methods more challenging. On the other hand, in terms of surface roughness and defects, silicon wafers typically have very smooth surfaces, which facilitate precise optical alignment. Silicon carbide substrates, due to their hardness and polishing difficulties, often have higher surface roughness and defects on their wafer surfaces, which can affect alignment accuracy. Additionally, regarding the visibility of alignment marks, alignment marks on silicon wafers are generally easy to etch and optically detect. However, for silicon carbide substrates, alignment marks are more difficult to detect optically, thus requiring alternative methods such as etch depth analysis or fluorescence imaging.

As described above, in semiconductor processes related to silicon carbide substrates, optimizing alignment marks to overcome issues such as opacity, roughness, and visibility of alignment marks, thereby improving the efficiency of the photolithography process and reducing the frequency of rework, is a critical challenge that the industry urgently needs to address.

### SUMMARY OF THE INVENTION

The primary objective of this invention is to provide an innovative alignment mark for silicon carbide semiconductor process and a manufacturing method thereof. By forming trench structures or island structures on a silicon carbide substrate and using an ion implantation process to disrupt the lattice arrangement at the bottom of the trench or island structures, causing lattice distortion, the resulting structure serves as an alignment mark for subsequent processes. This enhances the alignment signal strength and increases the contrast difference between the alignment mark and the background, thereby improving the efficiency of the photolithography process and reducing the frequency of rework.

To achieve the above objective, this invention provides an alignment mark for silicon carbide semiconductor process, wherein the alignment mark is formed on a silicon carbide epitaxial layer of a silicon carbide substrate and comprises at least one trench structure and an ion doped interface. The at least one trench structure is disposed in the silicon carbide epitaxial layer, and the ion doped interface is disposed at a bottom of the at least one trench structure.

In one embodiment of the alignment mark for silicon carbide semiconductor process of this invention, the trench structure has a depth of 0.5 to 1 micrometer (μm).

In one embodiment of the alignment mark for silicon carbide semiconductor process of this invention, the trench structure has an aspect ratio of not less than 3.

In one embodiment of the alignment mark for silicon carbide semiconductor process of this invention, the ion doped interface is a P-type ion doped interface or an N-type ion doped interface.

To achieve the above objective, this invention provides an alignment mark for silicon carbide semiconductor process, wherein the alignment mark is formed on a silicon carbide epitaxial layer of a silicon carbide substrate and comprises at least one island structure and an ion doped interface. The island structure is disposed in the silicon carbide epitaxial layer, wherein the island structure comprises a plurality of trench structures, and the trench structures are interconnected at an upper surface of the silicon carbide epitaxial layer to form a continuous recessed structure. The ion doped interface is disposed at a bottom of the island structure.

To achieve the above objective, this invention provides a manufacturing method for an alignment mark for silicon carbide semiconductor process, comprising the following steps. First, provide a silicon carbide epitaxial layer on a silicon carbide substrate. Next, provide a trench structure disposed in the silicon carbide epitaxial layer. Finally, provide an ion doped interface disposed at a bottom of the trench structure.

In one embodiment of the manufacturing method of the alignment mark of this invention, the step of providing a trench structure is to provide a trench structure with a depth of 0.5 to 1 micrometer (μm).

In one embodiment of the manufacturing method of the alignment mark of this invention, the step of providing a trench structure is to provide a trench structure with an aspect ratio of not less than 3.

In one embodiment of the manufacturing method of the alignment mark of this invention, the step of providing an ion doped interface is to provide a P-type ion doped interface or an N-type ion doped interface.

To achieve the above objective, this invention provides a manufacturing method for an alignment mark, comprising the following steps. First, provide a silicon carbide epitaxial layer on a silicon carbide substrate. Next, provide a plurality of trench structures disposed in the silicon carbide epitaxial layer, wherein the trench structures are interconnected at an upper surface of the silicon carbide epitaxial layer to form a continuous recessed structure for forming an island structure. Finally, provide an ion doped interface disposed at a bottom of the island structure.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1A to FIG. 5A are top-view schematic diagrams illustrating the manufacturing process of an alignment mark for silicon carbide semiconductor process in one embodiment of this invention;

FIG. 1B to FIG. 5B are cross-sectional schematic diagrams illustrating the manufacturing process of an alignment mark for silicon carbide semiconductor process in one embodiment of this invention;

FIG. 6A is a top-view schematic diagram of an alignment mark with an island structure in one embodiment of this invention;

FIG. 6B is a schematic diagram comparing the contrast difference between the alignment mark and the background with and without ion implantation in one embodiment of this invention; and

FIG. 7 is a flowchart schematic diagram of the manufacturing process of an alignment mark in one embodiment of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

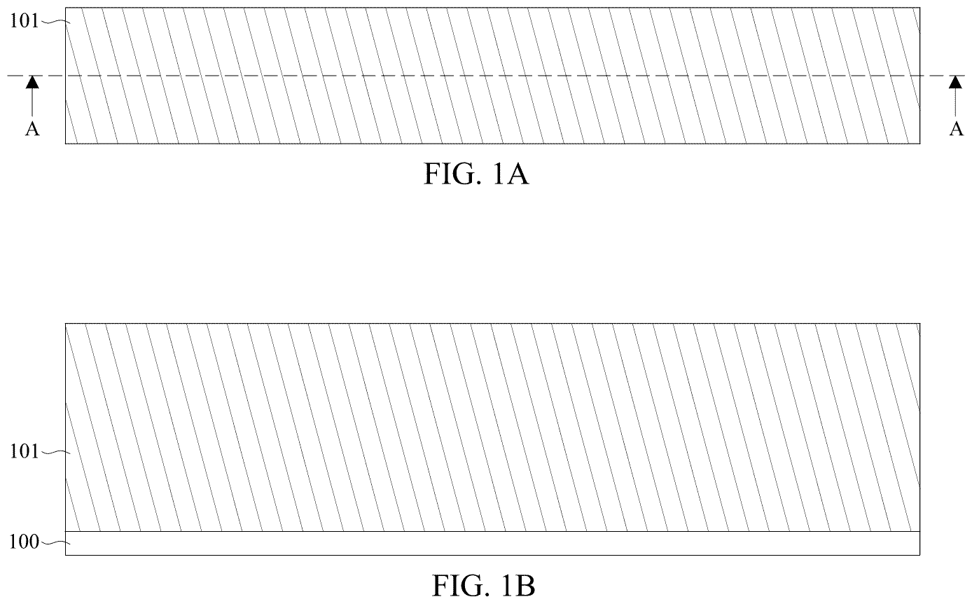

Please refer to FIG. 1A and FIG. 1B, wherein FIG. 1A is a top-view schematic diagram showing a silicon carbide epitaxial layer 101 epitaxially grown on a silicon carbide substrate 100, and FIG. 1B is a cross-sectional schematic diagram along the line AA in FIG. 1A. It should be noted that, for clarity of illustration, subsequent figures are similar to FIG. 1A and FIG. 1B, simultaneously showing top-view schematic diagrams and cross-sectional schematic diagrams along the line AA in the respective figures.

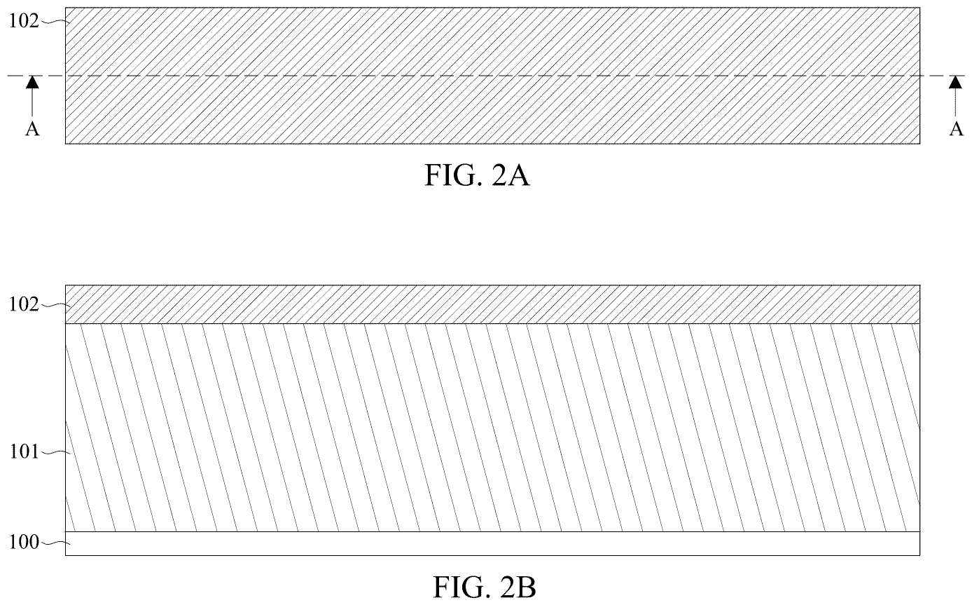

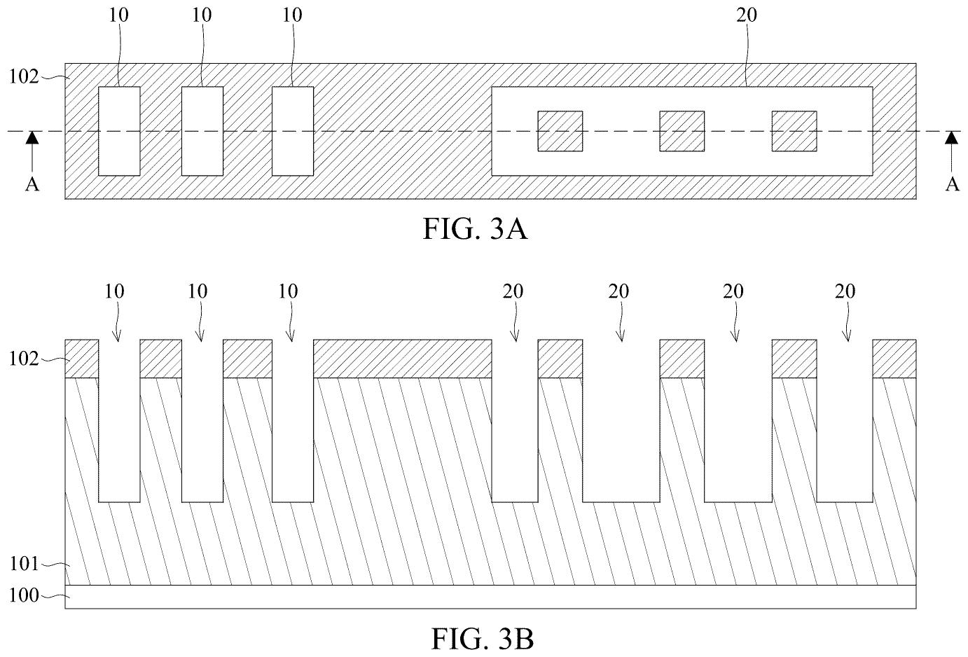

Next, an oxide layer 102, such as a silicon dioxide layer, is grown on the surface of the silicon carbide epitaxial layer 101 using thermal oxidation or chemical vapor deposition (CVD), as shown in FIG. 2A and FIG. 2B. Then, the oxide layer 102 is subjected to a patterned etching process using dry etching or wet etching, transforming the oxide layer 102 into a patterned hard mask. Subsequently, using the patterned oxide layer 102 as a hard mask, the silicon carbide epitaxial layer 101 is etched by dry etching or wet etching to form a plurality of trench structures 10 and/or an island structure 20 in the silicon carbide epitaxial layer 101, as shown in FIG. 3A and FIG. 3B. The island structure 20 is formed by a plurality of trench structures arranged adjacent to each other in the silicon carbide epitaxial layer, interconnected at the upper surface of the silicon carbide epitaxial layer 101 and the oxide layer 102 to form a continuous recessed structure, as shown in FIG. 3A and FIG. 3B.

Preferably, the etching process for forming the trench structures uses reactive-ion etching (RIE) or inductively coupled plasma (ICP) etching to form trench structures with a high aspect ratio in the silicon carbide epitaxial layer 101. In a preferred embodiment, each trench structure 10 and the trench structures in the island structure 20 have a depth of 0.5 to 1 micrometer (μm), optimally 0.8 micrometer (μm). Additionally, each trench structure 10 and the trench structures in the island structure 20 have an aspect ratio (AR) of not less than 3.

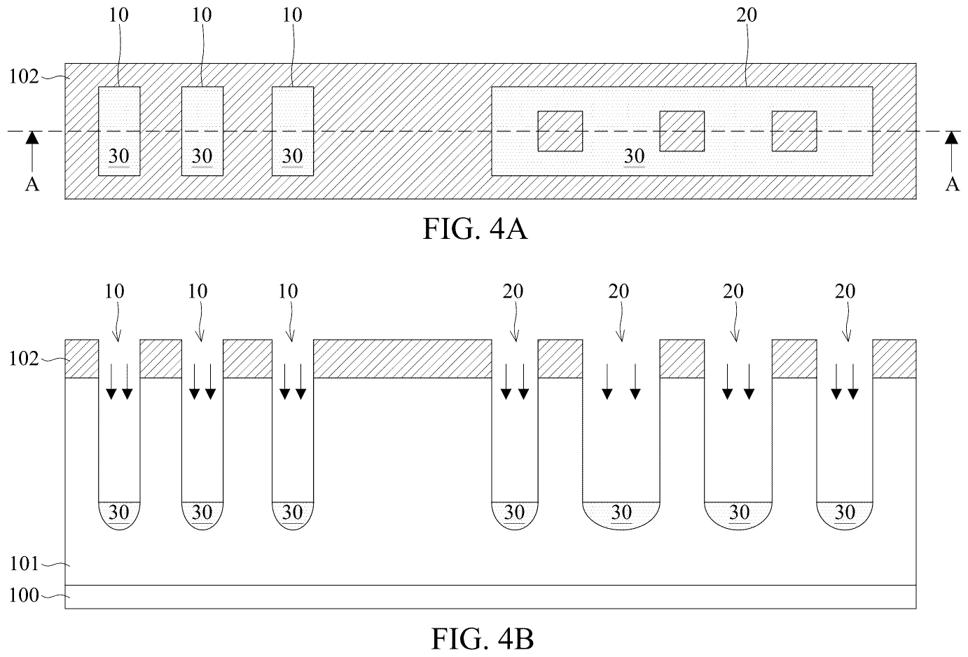

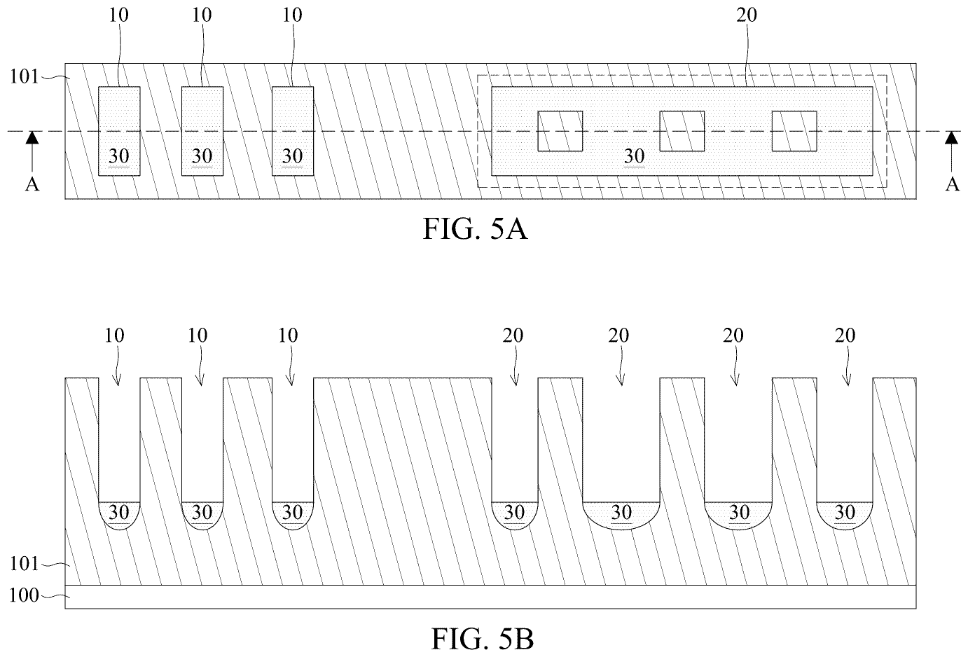

Please refer to FIG. 4A and FIG. 4B, where a blanket ion implantation process is performed on the surface of the silicon carbide substrate. By adjusting appropriate ion implantation concentration and energy, ions are implanted into the silicon carbide epitaxial layer 101 exposed outside the patterned oxide layer 102. Specifically, ion implantation disrupts the exposed silicon carbide lattice at the bottom of each trench structure 10 and/or the bottom of the island structure 20, thereby forming an ion doped interface 30 to enhance the contrast between the alignment mark and its background region. Specifically, the ion implantation can be P-type ion implantation or N-type ion implantation, depending on the process and device requirements, to form a P-type ion doped interface or an N-type ion doped interface at the bottom of each trench structure 10 and/or the bottom of the island structure 20. Finally, as shown in FIG. 5A and FIG. 5B, the oxide layer 102 is removed to complete the alignment mark pattern with enhanced signal strength of this invention. It should be noted that, in practical applications, the trench structures 10, island structures 20, or other alignment mark patterns formed by interconnected trench structures disclosed in this invention can be formed individually or simultaneously on the silicon carbide substrate, depending on actual requirements.

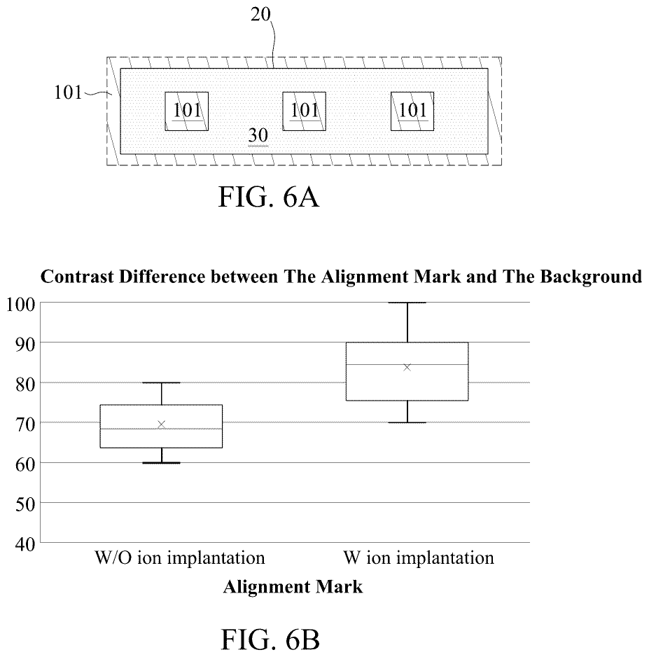

Please refer to FIG. 6A, which shows the island structure 20 as indicated by the dashed box in FIG. 5A, serving as an example of the alignment mark pattern for the silicon carbide semiconductor process of this invention. This island structure 20 is typically disposed at the edge or a specific region outside the active area of the silicon carbide substrate 100. The high aspect ratio of this island structure enables the optical alignment system to produce distinct image contrast for precise alignment in subsequent processes. In particular, since the bottom of the island structure 20 has an ion doped interface 30, this ion doped interface 30 has a disrupted lattice structure due to ion implantation, causing changes in refractive index and absorption rate for the light used in the alignment system. This enhances the contrast between the alignment mark and the background region, further improving alignment accuracy, increasing the efficiency of the photolithography process, and reducing the frequency of rework. As shown in FIG. 6B, it illustrates the contrast difference between the alignment mark and the background pattern under conditions with and without ion implantation in the embodiment shown in FIG. 6A. Clearly, adding ion implantation at the bottom of high aspect ratio trench structures or island structures significantly improves the contrast between the alignment mark and the background compared to the contrast without an ion doped interface. Thus, it can be seen that high aspect ratio trench structures or island structures combined with a bottom ion doped interface can substantially enhance the contrast between the alignment mark and the background region, thereby improving alignment accuracy.

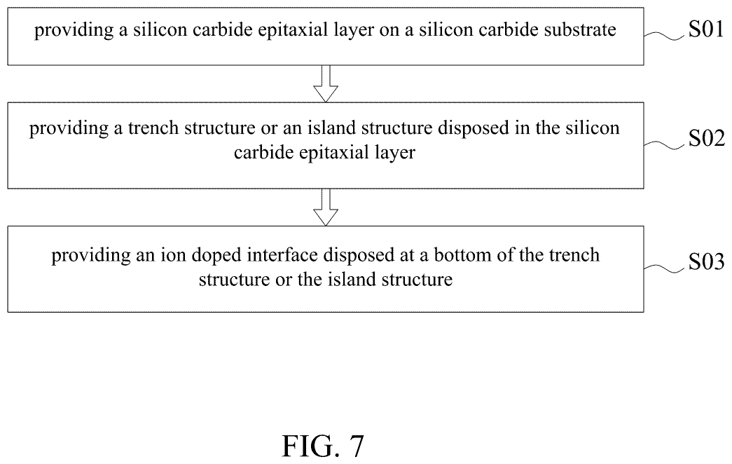

Please refer to FIG. 7, which illustrates a flowchart schematic diagram of the manufacturing method of the alignment mark of this invention. First, in step S01, a silicon carbide epitaxial layer is provided on a silicon carbide substrate. In step S02, a trench structure or an island structure is provided, disposed in the silicon carbide epitaxial layer. Next, in step S03, an ion doped interface is provided, disposed at a bottom of the trench structure or the island structure. The descriptions of the related components in the aforementioned process steps can be referred to the above content and will not be repeated here.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. An alignment mark for silicon carbide semiconductor process, formed on a silicon carbide epitaxial layer of a silicon carbide substrate, comprising:
a trench structure disposed in the silicon carbide epitaxial layer; and
an ion doped interface disposed at a bottom of the trench structure.

2. The alignment mark for silicon carbide semiconductor process of claim 1, wherein the trench structure has a depth of 0.5 to 1 micrometer (μm).

3. The alignment mark for silicon carbide semiconductor process of claim 1, wherein the trench structure has an aspect ratio of not less than 3.

4. The alignment mark for silicon carbide semiconductor process of claim 1, wherein the ion doped interface is a P-type ion doped interface or an N-type ion doped interface.

5. An alignment mark for silicon carbide semiconductor process, formed on a silicon carbide epitaxial layer of a silicon carbide substrate, comprising:
an island structure disposed in the silicon carbide epitaxial layer, wherein the island structure comprises a plurality of trench structures, and the trench structures are interconnected at an upper surface of the silicon carbide epitaxial layer to form a continuous recessed structure; and
an ion doped interface disposed at a bottom of the island structure.

6. The alignment mark for silicon carbide semiconductor process of claim 5, wherein the trench structure has a depth of 0.5 to 1 micrometer (μm).

7. The alignment mark for silicon carbide semiconductor process of claim 5, wherein the trench structure has an aspect ratio of not less than 3.

8. The alignment mark for silicon carbide semiconductor process of claim 5, wherein the ion doped interface is a P-type ion doped interface or an N-type ion doped interface.

9. A manufacturing method for an alignment mark, comprising:
providing a silicon carbide epitaxial layer on a silicon carbide substrate;
providing a trench structure disposed in the silicon carbide epitaxial layer; and
providing an ion doped interface disposed at a bottom of the trench structure.

10. The manufacturing method for an alignment mark of claim 9, wherein the step of providing a trench structure is to provide the trench structure with a depth of 0.5 to 1 micrometer (μm).

11. The manufacturing method for an alignment mark of claim 9, wherein the step of providing a trench structure is to provide the trench structure with an aspect ratio of not less than 3.

12. The manufacturing method for an alignment mark of claim 9, wherein the step of providing an ion doped interface is to provide a P-type ion doped interface or an N-type ion doped interface.

13. A manufacturing method for an alignment mark, comprising:
providing a silicon carbide epitaxial layer on a silicon carbide substrate;
providing a plurality of trench structures disposed in the silicon carbide epitaxial layer, wherein the trench structures are interconnected at an upper surface of the silicon carbide epitaxial layer to form a continuous recessed structure for forming an island structure; and
providing an ion doped interface disposed at a bottom of the island structure.
